(19) United States
(12) Patent Application Publication
(10) Pub. No.: US 2006/0097397 A1
(43) Pub. Date: May 11, 2006

(54) Method for forming a dual layer, low resistance metallization during the formation of a semiconductor device

(76) Inventor: Stephen W. Russell, Boise, ID (US)

Correspondence Address: Kevin D. Martin;Micron Technology, Inc., MS 1-525, 8000 S Federal Way, Boise, ID, 83716, US

(21) Appl. No.: 10/985,635

(22) Filed: Nov. 10, 2004

(51) Int. Cl. H01L 23/52; H01L 21/4763

(52) U.S. Cl. 257/762; 438/687; 438/675; 438/656; 257/774

(57) ABSTRACT

A method for providing a highly reliable, low resistance interconnect comprises forming a trench in a dielectric layer, forming a first liner in the trench then forming a resilient layer such as a tungsten layer within the trench. The resilient layer is etched back to remove the layer from a horizontal portion of the dielectric outside the trench and to recess the layer within the trench. Next, a second liner and a copper layer are formed in the trench over the resilient layer. The copper layer and exposed portions of the two liners are polished or etched back to result in the interconnect. Variations to this embodiment are also described.

### FIELD OF THE INVENTION

This invention relates to the field of semiconductor manufacture and, more particularly, to a conductive line comprising at least two metal layers and a liner, and a method for forming the conductive line.

### BACKGROUND OF THE INVENTION

Many structures are required during the manufacture of a semiconductor device, such as conductive plugs, transistors, capacitors, and conductive lines. A common design goal of semiconductor engineers is to decrease the size of these features to increase the number of features which can be formed in a given area. Decreasing feature size results in decreased production costs and, ultimately, miniaturized electronic devices into which the semiconductor device is installed.

Increasing electrical resistance is a concern with decreasing device feature size. For example, as the width of conductive lines decreases the resistance increases, especially with the relatively longer lines such as word lines in memory devices and conductive interconnects. Dynamic random access memory (DRAM) access transistor word lines, for example, were originally manufactured from conductively-doped polysilicon. As the line widths decreased a more conductive enhancement layer, typically tungsten silicide, was formed over the polysilicon to reduce overall resistance of the word lines. Word lines have decreased in size to the point that they are more commonly manufactured from a three-layer stack of polysilicon, tungsten nitride, and tungsten metal to enhance conductivity.

Size reduction also affects the conductivity of other conductive lines such as conductive interconnects. Materials such as refractory metals provide reliable interconnects, but have a relatively high resistance. The resistance of refractory metal interconnects is sufficiently low that larger interconnects propagate signals and voltages adequately, but below a certain cross-sectional area, depending on the use, the resistance becomes excessively high. Other metals such as copper and aluminum have lower resistance which is acceptable for smaller conductive interconnects, but with use they may develop defects which worsen with further use so that electrical opens form, ultimately leading to an unreliable or nonfunctional device. Copper also may migrate under a subsequently-formed dielectric layer due to electromigration, which may then short the copper feature with an adjacent conductor thus rendering the device unstable or inoperable.

Various methods for forming interconnects have been used in the attempt to provide a reliable, low-resistance interconnect. For example, U.S. Pat. No. 6,157,081 by Nariman discusses a process wherein a trench is at least 80% filled with copper, then a high-temperature conductor such as tungsten is formed over the copper within the trench. This reduces or eliminates the problem of electromigration. However, it relies on partial fill of trenches with copper such as by an etch back process. Copper is very difficult to etch due to the absence of volatile halide species except at high temperatures, which are typically avoided. Nariman '081 also relies on either an additional pattern and etch to remove tungsten from the field regions between interconnect lines, or a planar polish to isolate interconnect lines. The former solution is a high cost adder due to the additional masking step and has the additional disadvantage of requiring an extremely tight alignment tolerance. The latter solution requires a second polish at every metal level, and in addition requires development of a tungsten polish (a hard metal) which exhibits lower dielectric loss. This is not a common property of tungsten polishes. Even minimal dielectric loss or erosion will completely remove a thin tungsten cap layer, which negates the benefit of this process.

A method for forming a highly-reliable, low resistance interconnect and the resulting structure which solves the problems discussed above would be desirable.

### SUMMARY OF THE INVENTION

The present invention provides a new method which reduces problems associated with the manufacture of semiconductor devices, particularly problems resulting from decreasing cross sectional areas of reliable, high resistance contacts, and unreliable, low resistance interconnects.

An embodiment of the invention comprises the formation of one or more interconnect trenches within a dielectric layer. The trench is lined with a conductive layer, then a resilient metal such as tungsten or another refractory metal is formed over the liner which may fully or partially fill the trench. An etch back is performed to recess the resilient metal within the trench. Next, a second liner is formed over the resilient metal and a copper layer is formed over the second liner to fill the trench. The copper layer is planarized with an etch back, more preferably with a chemical mechanical polish, or with a combination of the two such that the copper just fills the remainder of the trench.

The etch back of the resilient metal is more easily accomplished than a damascene process which uses mechanical polishing or chemical-mechanical polishing (CMP) of a tungsten layer. Such a damascene process requires polishing of a hard metal with little dielectric loss, which is not easily accomplished. With the present invention the resilient material is recessed and is therefore etched with an etch back rather than with a CMP process. Further, the CMP of copper is preferred over a copper etch back, which requires high temperature processing to enable a copper etch with a halide species.

Additional advantages will become apparent to those skilled in the art from the following detailed description read in conjunction with the appended claims and the drawings attached hereto.

### BRIEF DESCRIPTION OF THE DRAWINGS

FIGS. 1-7 are cross sections depicting intermediate structures provided during one embodiment of the invention to form a semiconductor device;

FIG. 8 is a cross section along A-A of FIG. 7 depicting an intermediate structure provided during an embodiment of the invention when filling a wide trench;

FIG. 9 is an isometric depiction of various components which may be manufactured using devices formed with an embodiment of the present invention; and

FIG. 10 is a block diagram of an exemplary use of the invention to form part of a memory device having a storage transistor array.

It should be emphasized that the drawings herein may not be to exact scale and are schematic representations. The drawings are not intended to portray the specific parameters, materials, particular uses, or the structural details of the invention, which can be determined by one of skill in the art by examination of the information herein.

### DETAILED DESCRIPTION OF THE PREFERRED EMBODIMENT

The term “wafer” is to be understood as a semiconductor-based material including silicon, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “wafer” in the following description, previous process steps may have been utilized to form regions or junctions in or over the base semiconductor structure or foundation. Additionally, when reference is made to a “substrate assembly” in the following description, the substrate assembly may include a wafer with layers including dielectrics and conductors, and features such as transistors, formed thereover, depending on the particular stage of processing. In addition, the semiconductor need not be silicon-based, but could be based on silicon-germanium, silicon-on-insulator, silicon-on-sapphire, germanium, or gallium arsenide, among others. Further, in the discussion and claims herein, the term “on” used with respect to two layers, one “on” the other, means at least some contact between the layers, while “over” means the layers are in close proximity, but possibly with one or more additional intervening layers such that contact is possible but not required. Neither “on” nor “over” implies any directionality as used herein.

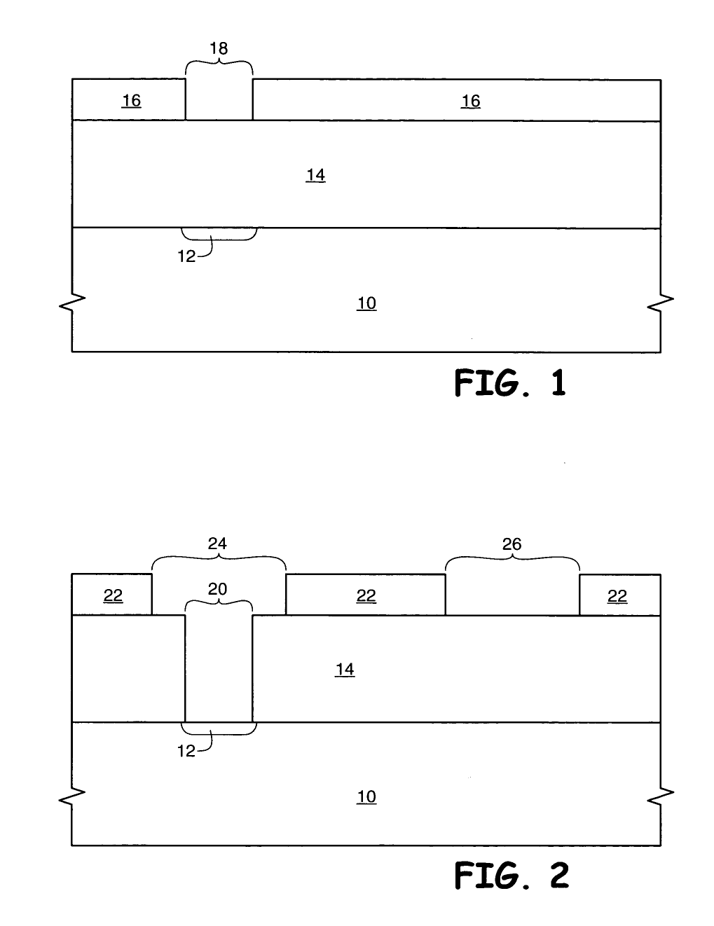

A first embodiment of an inventive method for forming a low resistance, high reliability interconnect and a contact to a doped region with a semiconductor wafer using a dual damascene process is depicted in FIGS. 1-7. FIG. 1 depicts the following structures: a semiconductor wafer 10 having a conductively-doped region 12 therein; a silicon dioxide or low-k layer dielectric layer 14 such as a layer of borophosphosilicate glass (BPSG), tetraethyl orthosilicate (TEOS), a combination of one or more layers of each, or a spun-on layer; and a photoresist layer 16 having an opening therein 18 which defines an opening to region 18. In this exemplary embodiment the dielectric layer is between about 1,000 angstroms (Å) thick and about 20,000 Å (20 KÅ) thick, and the opening 18 is between about 50 Å and about 50 micrometer (μm) wide. As opening 18 will be used to form a contact opening to doped region 12, opening 18 will typically be round, oval, square, or rectangular in shape. It should be further noted that contact to doped wafer region 12 is only one exemplary use of the invention. Contact may also be made to various other layers, for example features formed from doped polysilicon, tungsten, copper, silicide, or other metals or conductive nonmetals.

The structure of FIG. 1 is etched to expose the wafer at doped region 12 and to result in the contact opening 20 of FIG. 2. In the depicted embodiment opening 20 is etched completely through the 20 KÅ thick dielectric layer 14. In other embodiments, the opening 20 may be etched only part way into dielectric 14, for example between about 2,000 Å and about 20 KÅ deep, and completed with a subsequent etch. In either case, dielectric 14 can be etched easily by one of ordinary skill in the art from the description herein. After etching the contact opening 20, photoresist layer 16 is removed and another patterned photoresist layer 22 is formed. Photoresist layer 22 comprises a first opening 24 which exposes opening 20 and a second opening 26 which will provide a conductive interconnect. Both of openings 24 and 26 are between about 50 Å and about 50,000 μm wide. A typical opening for an elongated interconnect may be at least 500 Å long, and may be up to 50,000 μm long. As openings 24, 26 are depicted in cross section, the lengths of the openings are not depicted.

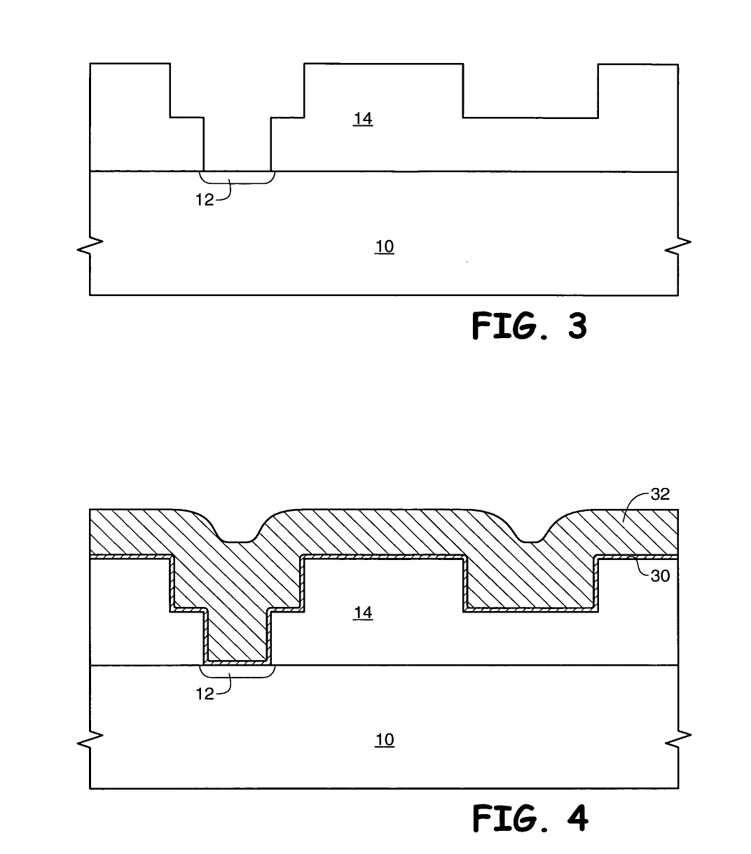

Subsequently, the FIG. 2 structure is etched to provide the openings in dielectric layer 14 as depicted in FIG. 3. As depicted in FIG. 4, a first conformal conductive liner 30, for example titanium metal, titanium nitride, or tungsten nitride is formed to between about 5 Å and about 500 Å thick. This liner can be formed using a chemical vapor deposition (CVD) process, a physical vapor deposition (PVD) process, a plasma-enhanced CVD (PECVD) process, or a combination of two or more of these processes. Layer 30 can be formed by one of ordinary skill in the art, for example in a deposition chamber such as one from Applied Materials of Santa Clara, Calif. through the use of a titanium precursor such as titanium tetrachloride (TiCl₄). The liner prevents contamination of dielectric layer 14 or wafer 10 from subsequently-formed metal layers, and functions as an adhesion layer between the silicon wafer 10, the dielectric layer 14, and subsequently-formed layers.

After forming liner 30, resilient conductive layer 32 (i.e. a material which is more robust than copper) is formed within the etched openings. Preferred materials include refractory metals (metals with boiling points greater than about 4,000° C.), for example tungsten. For the openings in dielectric layer 14 of the present embodiment, the resilient conductive layer 32 has a target thickness of between about 500 Å and about 10 KÅ. A tungsten layer can be formed by providing tungsten hexafluoride (WF₆) in the chamber while maintaining the chamber temperature to between about 200° C. and about 500° C. This layer forms at a rate of between about 5 Å/second and about 500 Å/second, so for the layer of this embodiment the process is continued for between about one minute and about 15 minutes to result in the structure of FIG. 3.

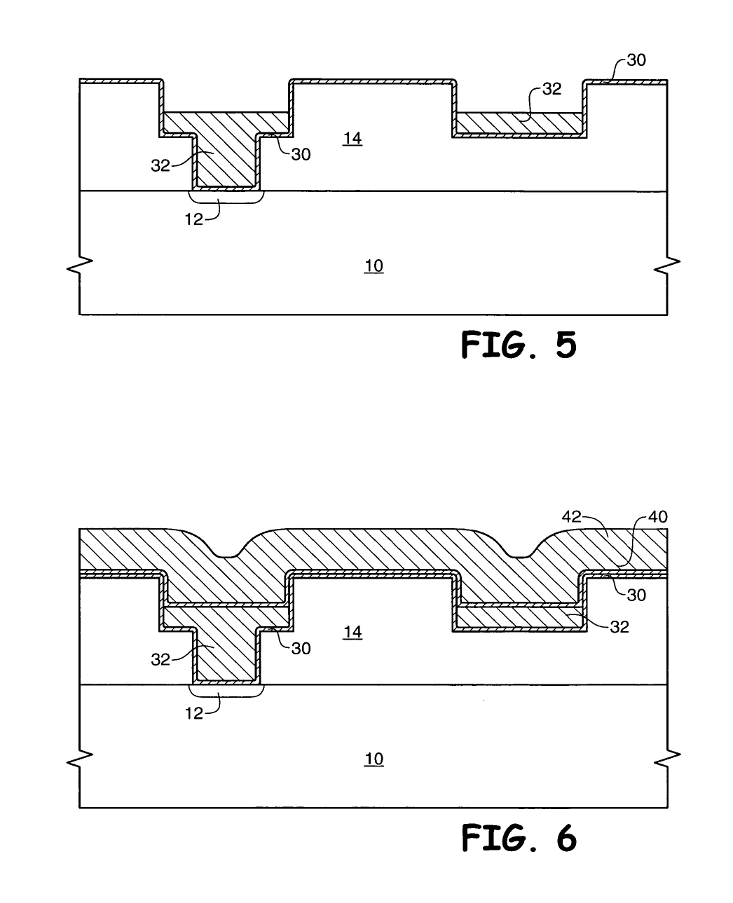

A tungsten etch back (or other etch back, depending on the material used) is performed on the resilient layer 32 to recess the layer 32 as depicted in FIG. 5. For tungsten, an etch back comprises exposing the layer to an etch comprising sulfur hexafluoride (SF₆), boron trichloride (BCl₃), chlorine (Cl₂), or other common halides or halide-containing species. This etch back may also remove layer 30 from the horizontal surface of layer 14 outside the trenches, or layer 30 may be removed during a subsequent CMP or etch back described below. To optimize the electrical properties of the conductive interconnect, the resilient layer 32 in the opening of dielectric 14 on the right side of FIG. 4 is targeted to fill between 5% and 50% of the volume of the trench. With a decreasing fill of resilient layer 32 below about 5% reliability benefits will be negated. This negation results from an excessive percentage of copper which is prone to void formation, and a resilient layer having a trench fill of less than 5% by volume is not sufficient to take over functionality of the interconnect should an electrical open occur within the copper layer. Conversely, if more than about 50% of the trench is filled with resilient material the resistance of the conductive interconnect will be excessive from insufficient copper. An excessive percentage of resilient material within the trench may result in an unreliable device, for example because of excessive signal propagation delay.

After recessing layer 32 within the trench, a second liner 40 and a copper metal layer 42 are formed as depicted in FIG. 6. The second liner 40, which may be between 5 Å and 5,000 Å thick, separates layer 32 from copper layer 42 and reduces or eliminates copper diffusion, and functions as an adhesion layer between copper layer 42 and resilient layer 32. Second liner 42 may be manufactured from a number of different materials, for example tantalum, tantalum nitride, tantalum silicon nitride, tantalum carbon nitride, tantalum carbide, titanium, titanium nitride, tungsten, tungsten nitride, tungsten carbide, tungsten carbon nitride, tungsten silicon nitride, or a combination of two or more layers. The copper layer, with the present embodiment, has a targeted thickness of between about 1,000 Å and about 20 KÅ thick or sufficiently thick to completely fill the remainder of the trenches and to provide process margin sufficient to over polish the layer.

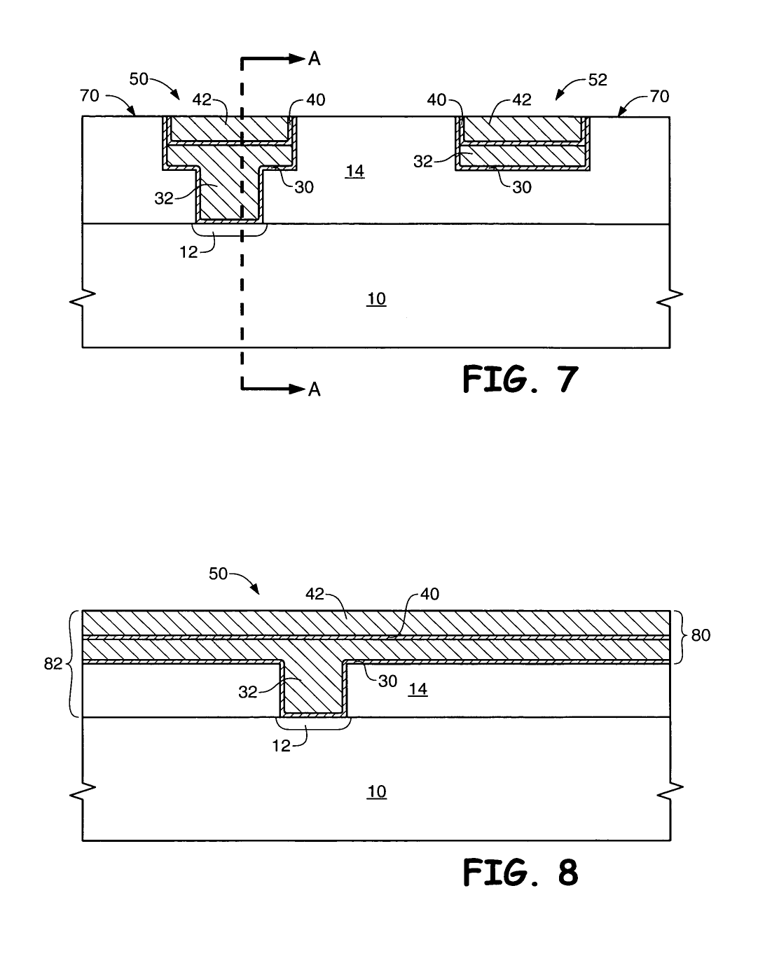

After forming the structure of FIG. 6, a copper etch back or, more preferably, a chemical mechanical polishing (CMP) is performed to result in the structure of FIG. 7. As depicted, this step will remove layer 40 from horizontal surfaces outside the trench, as well as layer 30 if layer 30 was not removed during the etch of layer 32 at FIG. 4. This CMP step forms an upper surface of copper 42 which generally continuous with the horizontal major surface 70 of layer 14. For purposes of this disclosure, “generally continuous” refers to the surface of the copper 42 which has been planarized to be flush with the surface of dielectric 14, but may have some surface irregularities resulting from processing variations.

Metal feature 50 of FIG. 7 has thus been formed using a dual damascene process and functions both as a plug and as an interconnect while metal feature 52 is depicted as only an interconnect (but may also be connected to a plug formed at a location not depicted) and may, in actuality, be formed using either a single or dual damascene process depending on the use of the interconnect. Further, while the resilient layer will fill only between 5% and 50% of the trench 52, it may fill more than 50% of the plug portion 50 of a dual damascene plug/interconnect combination as depicted. A cross section along A-A of metal feature 52 is depicted in FIG. 8, which illustrates that metal 32 fills 50% or less of the interconnect portion 80 of the plug/interconnect combination, but that metal 32 may fill more than 50% of the plug portion (height depicted at 82) defined by a receptacle in the first liner of the plug/interconnect combination.

The resulting interconnect structure of FIGS. 7 and 8 is an advantage over a purely copper interconnect because if the copper develops one or more voids and fails, the resilient metal layer under the copper can bridge the void and carry the signal across the void. The FIG. 7 structure is an advantage over an interconnect comprising a copper layer covered by a more resilient but higher resistance layer, for example because it can be formed using traditional processes. That is, the present embodiment of the inventive process does not require a copper etch back process which can result in halide contamination of the copper as well as voids produced during high temperature etching. Further, it does not require a copper etch back to recess the copper layer within the trench, which requires a higher processing temperature for halide etching, which undesirably consumes a portion of the thermal budget and stresses the device, particularly at material interfaces. Finally, replacing tungsten CMP with a tungsten etch back for dual damascene reduces costs and simplifies processing.

Forming the conductors within the trench using the processes described above reduces or eliminates keyholing which may occur with some conventional processes. Keyholing as known in the art results in the formation of a vertically-oriented void at the center of the conductive feature which occurs when a trench is filled with a single layer of adhesive or is filled with more than one layer without one or more intermediate etches between layer formation. Keyholing is generally avoided as it results in an increased resistance of the completed structure as well as providing a substantial reliability risk due to copper migration into the keyhole and subsequent creation of an electrical open.

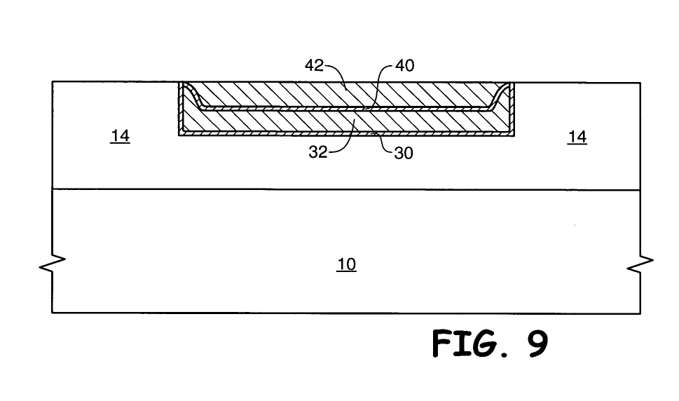

It should be noted that, depending on the width-to-height ratio of the trench, the conductor may have a different profile to that of FIG. 7. FIG. 9, for example, depicts a trench having a high width-to-height ratio which may be provided during the formation of buses or other conductive features. A cross section of the conductive layers which fill the trench may have a spacer appearance similar to that depicted.

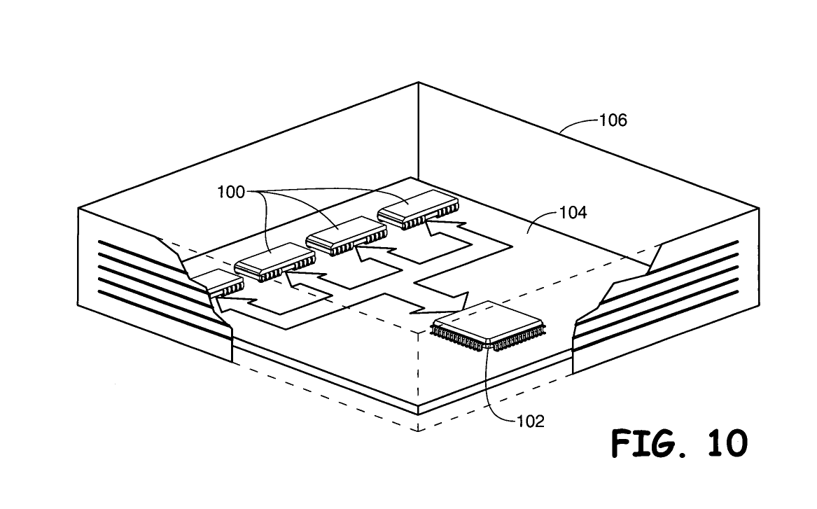

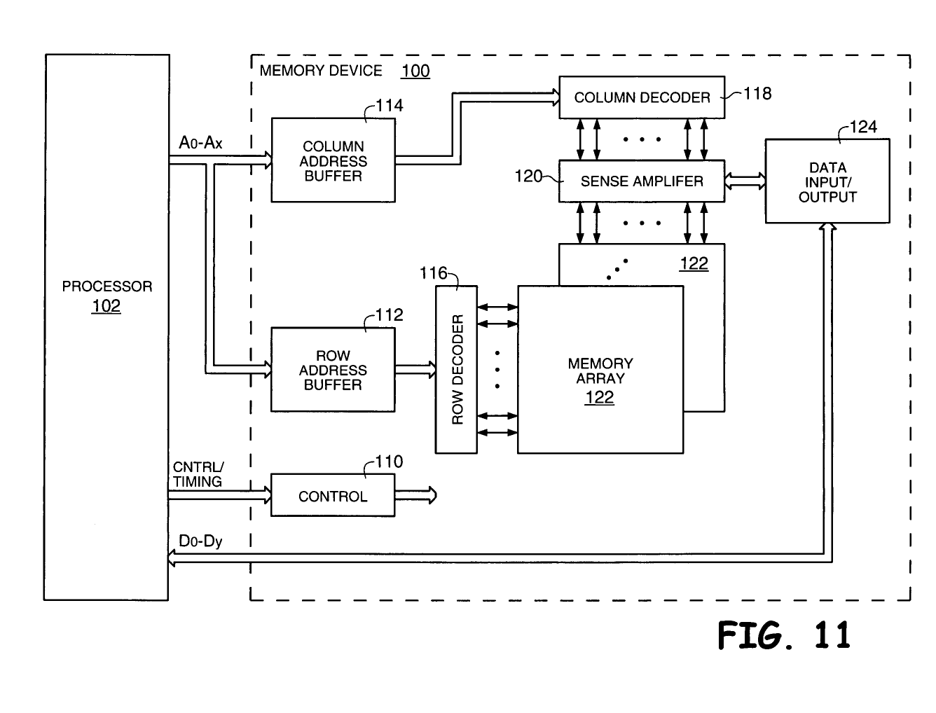

As depicted in FIG. 10, a semiconductor device 100 formed in accordance with the invention may be attached along with other devices such as a microprocessor 102 to a printed circuit board 104, for example to a computer motherboard or as a part of a memory module used in a personal computer, a minicomputer, or a mainframe 106. FIG. 10 may also represent use of device 100 in other electronic devices comprising a housing 106, for example devices comprising a microprocessor 102, related to telecommunications, the automobile industry, semiconductor test and manufacturing equipment, consumer electronics, or virtually any piece of consumer or industrial electronic equipment.

The process and structure described herein can be used to manufacture a number of different structures which comprise a structure formed using a photolithographic process. FIG. 11, for example, is a simplified block diagram of a memory device such as a dynamic random access memory having digit lines and other features which may be formed using an embodiment of the present invention. The general operation of such a device is known to one skilled in the art. FIG. 11 depicts a processor 102 coupled to a memory device 100, and further depicts the following basic sections of a memory integrated circuit: control circuitry 110; row 112 and column 114 address buffers; row 116 and column 118 decoders; sense amplifiers 120; memory array 122; and data input/output 124.

While this invention has been described with reference to illustrative embodiments, this description is not meant to be construed in a limiting sense. Various modifications of the illustrative embodiments, as well as additional embodiments of the invention, will be apparent to persons skilled in the art upon reference to this description. It is therefore contemplated that the appended claims will cover any such modifications or embodiments as fall within the true scope of the invention.

What is claimed is:

1. A method used during the formation of a semiconductor device, comprising:
providing a dielectric layer comprising at least one trench therein;
forming a first liner to line the trench;
forming a refractory metal blanket layer on the first liner;
performing an etch back of the refractory metal blanket layer such that the etched refractory metal layer fills between 5% and 50% of the volume of the trench;
forming a second liner which contacts the etched refractory metal layer;
forming a copper metal blanket layer on the second liner; and
polishing the copper metal blanket layer to result in a polished copper layer which fills the trench and is planarized with an upper surface of the dielectric layer.

2. The method of claim 1 wherein the polishing of the copper metal blanket layer is a chemical mechanical polish.

3. The method of claim 1 wherein the etch back of the refractory metal comprises exposing the refractory metal to an etchant comprising a halide.

4. The method of claim 3 wherein the halide-comprising etchant comprise a material selected from the group consisting of sulfur hexafluoride, boron trichloride, and chlorine.

5. The method of claim 1 further comprising polishing the first liner during the polishing of the copper metal blanket layer to result in a first liner which is planarized with the upper surface of the dielectric layer.

6. The method of claim 1 further comprising forming the second liner to contact the first liner.

7. The method of claim 1 further comprising:
forming a conductive region;
providing the dielectric layer over the conductive region;
etching the dielectric layer to expose the conductive region; and
forming the first liner to contact the conductive region,
wherein the refractory metal layer is electrically coupled with the conductive region through the first liner, and the copper layer is electrically coupled to the conductive region through the second liner, the refractory metal layer, and the first liner.

8. A method used to form a conductive interconnect during the formation of a semiconductor device, comprising:
forming a silicon dioxide layer comprising a major surface and an elongated trench;
forming a first conformal liner on the major surface and within the trench;
forming a refractory metal layer within the trench, over the major surface of the silicon dioxide layer, and on the first conformal liner;
performing an etch back on the refractory metal layer to recess the refractory metal layer within the trench and removing the refractory metal layer from over the major surface of the silicon dioxide layer;
subsequent to performing the etch back of the refractory metal layer, forming a second conformal liner on the refractory metal layer;
forming a conformal copper layer on the second conformal liner and within the trench; and
removing the copper layer from over the major surface of the silicon dioxide layer and leaving the copper layer within the trench to form an upper surface of the copper layer which is generally continuous with the major surface of the silicon dioxide layer.

9. The method of claim 8 wherein the etch back of the refractory metal layer leaves sufficient refractory metal to fill the trench to between 5% and 50% of the volume of the trench.

10. The method of claim 8 wherein the removal of the copper layer from over the major surface of the silicon dioxide layer is performed using chemical mechanical planarization.

11. The method of claim 8 wherein the etch back of the refractory metal layer is performed using titanium tetrachloride.

12. The method of claim 8 further comprising forming the first conformal liner from a material selected from the group consisting of titanium, titanium nitride, and tungsten nitride.

13. The method of claim 12 further comprising forming the second conformal liner from at least one material selected from the group consisting of tantalum, tantalum nitride, tantalum silicon nitride, tantalum carbon nitride, tantalum carbide, titanium, titanium nitride, tungsten, tungsten nitride, tungsten carbide, tungsten carbon nitride, and tungsten silicon nitride.

14. The method of claim 9 further comprising removing the first and second conformal liners from over the major surface of the silicon dioxide during the removal of the copper layer from over the major surface.

15. The method of claim 8 further comprising:
forming a conductive layer;
forming the silicon dioxide layer over the conductive layer;
etching the silicon dioxide layer to expose the conductive layer; and
forming the first conformal liner to contact the conductive layer,
wherein the refractory metal layer is electrically coupled with the conductive layer through the first liner, and the copper layer is electrically coupled to the conductive layer through the second liner, the refractory metal layer, and the first liner.

16. A semiconductor device comprising:
a dielectric layer having a major surface and a trench therein;
a refractory metal layer within the trench which fills between 5% and 50% of the volume of the trench; and
a copper layer within the trench over the refractory metal layer, the copper layer comprising an upper surface which is generally continuous with the major surface of the dielectric layer.

17. The semiconductor device of claim 16 further comprising:
a first liner lining the trench under the refractory metal layer; and
a second liner interposed between the copper layer and the refractory metal layer.

18. A semiconductor interconnect comprising, in a vertical cross-section:
a first liner material defining a first elongated interconnect receptacle;
a refractory metal filling a portion of the first elongated interconnect receptacle defined by the first liner;
a second liner material covering the refractory metal and contacting the first liner, wherein the second liner material forms a second elongated interconnect receptacle; and
copper filling the second elongated interconnect receptacle, wherein a cross sectional area of the refractory metal filling the first elongated interconnect receptacle is equal to or less than a cross sectional area of the copper filling the second elongated interconnect receptacle.

19. The semiconductor interconnect of claim 18 further comprising:
the first liner material defining a first contact receptacle; and
the refractory metal filling the contact receptacle defined by the first liner, wherein a cross sectional area of the refractory metal within and directly over the contact receptacle defined by the first liner is greater than a cross sectional area of the copper directly over the contact receptacle.
